(19) United States
(12) Patent Application Publication
(10) Pub. No.: US 2026/0329173 A1
(43) Pub. Date: Oct. 22, 2026

(54) METHOD FOR MANUFACTURING AN EUV MIRROR COMPONENT, AND INTERMEDIATE PRODUCT OF AN EUV MIRROR COMPONENT

(71) Applicant: Carl Zeiss SMT GmbH, Oberkochen (DE)

(72) Inventors: Katharina BROCH, Aalen (DE); Hartmut Enkisch, Aalen (DE); Sebastian Strobel, Aalen (DE); Christoph Nottbohm, Ulm (DE); Peter Huber, Heidenheim (DE)

(21) Appl. No.: 19/692,873

(22) Filed: May 29, 2026

Related U.S. Application Data
(63) Continuation of application No. PCT/EP2024/081858, filed on Nov. 11, 2024.

(30) Foreign Application Priority Data
Nov. 30, 2023 (DE) 10 2023 212 037.2

(51) Int. Cl. G03F 7/00; G02B 5/08

(52) U.S. Cl. CPC G03F 7/0005; G02B 5/0891; G03F 7/702; G03F 7/70233

(57) ABSTRACT

The techniques disclosed herein relate to a method for manufacturing an EUV mirror component, in which method a multilayer coating system is applied to a surface of a mirror body substrate in order to form an optical surface that is highly reflective for EUV radiation. A temporary protective layer structure is created on the multilayer coating system. The protective layer structure comprises a protective layer and a sacrificial layer located between the protective layer and the multilayer coating system. The sacrificial layer is a layer produced by oxidising a layer of the multilayer coating system. The temporary protective layer structure is removed before the EUV mirror component is put into operation. The disclosed techniques also relate to an intermediate product of an EUV mirror component.

### CROSS-REFERENCE TO RELATED APPLICATION

This is a Continuation of International Application PCT/EP2024/081858, which has an international filing date of Nov. 11, 2024, and the disclosure of which is incorporated in its entirety into the present Continuation by reference. This Continuation also claims foreign priority under 35 U.S.C. § 119(a)-(d) to and also incorporates by reference, in its entirety, German Patent Applications DE 10 2023 212 037.2 filed on Nov. 30, 2023.

### FIELD

The disclosure relates to a method for fabricating an EUV mirror component. The disclosure also relates to an intermediate product of an EUV mirror component.

### BACKGROUND

Microlithographie projection exposure apparatuses are used for the manufacture of integrated circuits with particularly small structures. A photomask illuminated by very short-wave extreme ultraviolet radiation (EUV radiation) is imaged onto a lithography object in order to transfer the mask structure to the lithography object.

The projection exposure apparatus comprises a plurality of EUV mirrors having an optical surface at which the EUV radiation is reflected. In order to keep down the losses of EUV radiation within the projection exposure apparatus, the EUV mirrors have an optical surface with high reflectivity for EUV radiation. The optical surface is formed by a multilayer system off which incident EUV radiation is reflected.

In addition to the projection exposure apparatus itself, there are further optical systems that are operated in connection with microlithographic projection exposure apparatuses. These include, for example, measuring devices that are used to examine the reflectivity of EUV mirrors, devices for examining modules and subsystems, and measuring devices that are used to examine the properties or the state of photomasks. EUV mirrors are also used in such optical systems.

Between the application of the multilayer system to a mirror body substrate and the subsequent time when the relevant EUV mirror component is put into service, there is an intermediate phase during which the EUV mirror component can be exposed to various influences. For example, the EUV mirror component might be stored, packaged, transported or mounted. Further processing steps might also be performed on the EUV mirror component.

It has been found that the multilayer system can become contaminated or damaged in this intermediate phase. Possible impairments include mechanical damage caused by cutting processes (e.g., laser cutting), (chemical) layer damage caused by etching media, photoresists and/or solvents, contamination caused by environmental influences and/or inadequate removal of an applied layer (e.g., photoresist), particle contamination caused by inadequate removal of an applied layer (e.g., photoresist), change in surface termination due to chemical interactions of the surface within a structuring process, layer roughening by etching media, photoresists and/or solvents, diffusion of solvents and/or etching media through the EUV layer and resulting layer detachment in the later use of the EUV mirror component and light-based or particle-based radiation damage. All these influences can lead to an impairment of the multilayer system and hence to a reduced quality of the optical surface of the EUV mirror component.

### SUMMARY

The problem addressed by the techniques disclosed herein is that of presenting a method for manufacturing an EUV mirror component and an intermediate product of an EUV mirror component, with which these disadvantages are avoided. The problem may be solved through examples of the techniques disclosed herein.

In the method according to the disclosed techniques for manufacturing an EUV mirror component, a multilayer system is applied to a surface of a mirror body substrate in order to form an optical surface that is highly reflective for EUV radiation. A temporary protective layer structure is produced on the multilayer system. The protective layer structure comprises a protective layer and a sacrificial layer arranged between the protective layer and the multilayer system. The temporary protective layer structure is removed before the EUV mirror component is put into service.

The disclosed techniques are based on the insight that, owing to conflicting requirements, it is not entirely straightforward to protect the optical surface from impairments in the intermediate phase. It is true that protective layers are known in principle which can be applied to the multilayer system and which offer adequate protection against environmental conditions. However, it has proven difficult to remove such protective layers from the multilayer system again without damaging the multilayer system. By contrast, layers which can be removed easily and without impairing the multilayer system usually do not offer adequate protection against the strains encountered.

The disclosed techniques propose a temporary protective layer structure which comprises a protective layer and a sacrificial layer arranged between the protective layer and the multilayer system. The protective layer can be composed in such a way that it offers sufficient protection against the strains encountered. The fact that method steps of higher aggressiveness are required for the removal of such a protective layer can be accepted because the underlying sacrificial layer can prevent the aggressive method steps from acting down into the multilayer system. Following the removal of the protective layer, the sacrificial layer can be removed using less aggressive method steps. The less aggressive method steps may be selected in such a way that the multilayer system is not impaired.

The temporary protective layer structure can ensure that the multilayer system is not damaged during the intermediate phase between the application of the multilayer system to the mirror body substrate and the time when the EUV mirror component is put into service. After the temporary protective layer structure has been removed, the EUV mirror component can be put into service with an impeccable optical surface.

The multilayer system may comprise alternating layers of molybdenum and silicon. With such a coating, it is possible to reflect approximately 70% of the incident EUV radiation. The multilayer system can be optimized for the reflection of EUV radiation in the extreme ultraviolet spectral range with wavelengths between 5 nm and 30 nm, in particular with a wavelength of 13.5 nm.

The multilayer system can comprise a top layer which consists of a different material than the underlying alternating layers of the multilayer structure. After removal of the temporary layer structure, the top layer can form the surface of the EUV mirror component. During later operation of the EUV mirror component, the top layer can assume a protective function in order to, for example, counteract rapid degradation of the multilayer system. The top layer can consist of an inorganic material. For example, the top layer can consist of ruthenium, TiO₂ or rhenium. The top layer can have a thickness of between 1 nm and 20 nm, preferably a thickness of between 2 nm and 10 nm.

The sacrificial layer can be a layer that is applied to the multilayer system. The sacrificial layer can be applied directly to the top layer of the multilayer system. The material for the sacrificial layer can be selected to meet one or more of the following requirements. The sacrificial layer should be removable without residue and without damaging or contaminating the multilayer system; this may be achieved, in particular, by a high purity of the material of the sacrificial layer. The sacrificial layer should have good adhesion to the surface of the multilayer system. The sacrificial layer should form a good adhesion base for the protective layer. The sacrificial layer should have a good wetting behavior on the surface of the multilayer system. The surface of the sacrificial layer should have a lower roughness so that negative influences on subsequent processing steps are avoided.

In one embodiment, the sacrificial layer is a carbon layer. By preference, at least 80%, more preferably at least 90% and more preferably at least 99.99% of the carbon layer comprises carbon. Percentages in relation to proportions of substances in a layer relate to the number of particles present in the layer. The surface energy of carbon is lower than that of metals. A good coverage of the multilayer system is therefore to be expected. Carbon has the advantage that it can be removed by using a hydrogen plasma. There is no risk of damage to the multilayer system when a hydrogen plasma is used because the optical surface is exposed to a hydrogen plasma during EUV operation in any case. Other methods of removing the carbon layer are possible. The carbon layer can have a thickness of, for example, between 1 nm and 30 nm, preferably between 2 nm and 5 nm.

Alternative materials for the structure of the sacrificial layer include, for example: nitrides; high-purity, smooth-growing carbon compounds with a high sublimation point, such as higher acenes; carbon compounds with a low sublimation point that can be removed by heating to a temperature below 350° C.; metals; and 2D materials, such as graphene or transition metal dichalcogenides. The layer thickness is preferably less than 30 nm in the case of an organic material for the sacrificial layer. The layer thickness can be, for example, between 10 nm and 300 nm in the case of an inorganic sacrificial layer.

Possible methods for applying the sacrificial layer include sputtering, electron beam deposition, chemical vapor deposition, physical vapor deposition, atomic layer deposition, spin coating and spray coating. Combinations of these methods are also possible. In general, the sacrificial layer should be applied in such a way that the multilayer system is not damaged by the application of the sacrificial layer. In particular, a temperature of 350° C. should not be exceeded.

Instead of applying the sacrificial layer to the multilayer system, the sacrificial layer can also be produced by converting the top layer of the multilayer system. In one embodiment, the sacrificial layer is produced by oxidation of the top layer. The sacrificial layer being produced by oxidation is advantageous in that the additional layer application step for the sacrificial layer can be omitted. A further advantage may result from the fact that an oxide in the top layer of the multilayer system generally has only slight effects on the reflectivity of the optical surface for EUV radiation. Accordingly, it may be acceptable for the sacrificial layer not to be completely removed before the EUV mirror component is put into service and for residues of the oxide to remain. In this case too, however, at least a large majority of the sacrificial layer should be removed, in particular to an extent of at least 80%, preferably at least 90% and more preferably at least 95%.

It is also possible to produce a sacrificial layer with a first sub-layer and a second sub-layer. The first sub-layer adjoining the multilayer system can be optimized for easy removal. The second sub-layer of the sacrificial layer can be optimized for forming a suitable base for the application of the protective layer. For example, the second sub-layer of the sacrificial layer can form a surface which can be readily wetted by the material of the protective layer. It is also possible for the second sub-layer to form a separation layer between the protective layer and the first sub-layer of the sacrificial layer, for example if the material of the protective layer were aggressive toward the first sub-layer of the sacrificial layer. In addition to that, or as an alternative, the second sub-layer of the sacrificial layer can be chosen such that it has sufficient resistance to the deposition method by which the protective layer is applied and/or to the cleaning method by which the protective layer is removed.

The protective layer can be applied to the sacrificial layer after the sacrificial layer was produced. The material of the protective layer should be selected such that one or more of the following requirements are met: stable under mechanical load, stable vis--à-vis etching media, stable vis-à-vis photoresist and/or solvents, stable at temperatures of up to 350° C., an effective diffusion barrier for oxygen and/or photoresist and/or solvent, good adhesion to the sacrificial layer, low roughness so as not to adversely affect further processing steps, capable of being removed without residue and without damage to or contamination of the EUV layer. The thickness of the protective layer can be between 0.1 μm and 10 μm, for example.

In one embodiment, the protective layer is applied as a protective lacquer which has corresponding properties. In particular, the protective layer can be formed by a protective lacquer in the form of a photoresist. In one embodiment, the protective lacquer has good layer cohesion such that the protective layer can be peeled off from the sacrificial layer in a manner similar to a film. In the case of a protective layer in the form of a protective lacquer, the layer thickness can be, for example, between 1 μm and 10 μm.

In an alternative embodiment, the protective layer is formed by applying silicon dioxide (SiO₂). Silicon dioxide has sufficient resistance to fulfill the desired protective function. For example, an HF vapor etching process with a high selectivity for the removal of silicon dioxide can be used to remove a layer of silicon dioxide. In the case of a protective layer made of silicon dioxide, the layer thickness can be, for example, between 0.1 μm and 0.3 μm. The protective layer can also be formed from other suitable oxides, in particular from other suitable silicon oxides.

The protective layer and the sacrificial layer can be removed from the surface of the multilayer system in two separate processes. The protective layer and the sacrificial layer can also be removed from the surface of the multilayer system in a single process. In general, the protective layer and the sacrificial layer should be removed in such a way that one or more of the requirements specified below are observed. Damage to the multilayer system should be avoided. The protective layer and the sacrificial layer should be removed without residue such that no contamination remains on the surface of the multilayer system. Increased particle contamination or roughening of the surface of the multilayer system should be avoided. The use of suitable non-thermal methods or a suitable cooling of the substrate should ensure that a surface temperature of 350° C. is not exceeded.

Methods that are generally suitable for removing the protective layer and/or the sacrificial layer include: dry-chemical methods, such as, for example, use of HF vapor, CF₄, CHF₃, etc. ; plasma cleaning, for example via an H plasma and/or an O plasma; cleaning with an ion beam source; wet-chemical cleaning; laser cleaning; application of CO₂ beams; heat treatment at temperatures below 350° C. and/or suitable substrate cooling; peeling off the protective layer as a film. These cleaning methods can be combined with one another and/or applied successively during the removal of the protective layer and/or the sacrificial layer.

The use of a wet-chemical method for removing the protective layer may be advantageous if the protective layer is formed by a protective lacquer. In a wet-chemical method, the protective layer is treated with a liquid solvent in order to dissolve the structure of the protective layer. Wet-chemical methods generally have the advantage that particles and contamination are reliably removed both on the protective layer and in the interior of the protective layer. The solvent can be selected such that it does not attack the underlying sacrificial layer.

The use of a dry-chemical method for removing the protective layer may be expedient if the protective layer consists of silicon dioxide. In particular, the protective layer can be removed by using an HF vapor etching method which has a high selectivity for the removal of silicon dioxide. If the protective layer is completely dissolved in this way, particles and contamination can be removed both on the protective layer and within the protective layer.

If a contamination layer has formed on the protective layer structure or within the protective layer structure by, for example, deposition of particles or by oxidation, then said contamination layer can be removed before the layer lying underneath in each case is removed. One possible method for removing the contamination layer is the use of an oxygen plasma.

The removal of the protective layer may be followed by the removal of the sacrificial layer. For this purpose, a gentle method is appropriate in order to avoid damage to the multilayer system. For example, a generally suitable method lies in the application of a hydrogen plasma for removal purposes (H* plasma or H′ plasma). This applies, in particular, if the sacrificial layer is a carbon layer. The removal can be effected by hydrogen plasma even in the case of a sacrificial layer produced by oxidation of the top layer of the multilayer system. If required, this can be combined with a physical etching process, such as the prior use of a noble gas plasma. The noble gas plasma can be, for example, a neon plasma, an argon plasma or a krypton plasma.

The multilayer layer system can be applied to the mirror body substrate in a process chamber under vacuum conditions. The production of the sacrificial layer of the temporary protective layer structure according to the disclosed techniques can follow without the EUV mirror component leaving the process chamber. The risk of contamination is reduced if the vacuum is maintained between the application of the multilayer system and the production of the sacrificial layer.

Furthermore, the vacuum can be maintained until the protective layer of the temporary protective layer structure has also been applied. In one embodiment, the protective layer is produced in the same process chamber as the multilayer system.

The method can be carried out in such a way that the EUV mirror component is not subjected to any further processing steps during the intermediate phase between the production of the temporary protective layer structure and the removal of the temporary protective layer structure. The function of the protective layer structure may consist primarily in protecting the optical surface during transport and storage.

In another embodiment, one or more processing steps are performed on the EUV mirror component during the intermediate phase. In particular, the EUV mirror component can be subjected to a processing step in which material is removed from the multilayer structure and/or from the substrate of the EUV mirror component. For example, it is possible to perform a processing step in which structuring is produced on the optical surface of the EUV mirror component. The structuring can be produced using a lithography method. To this end, a photoresist applied to the optical surface of the EUV mirror component can be exposed locally in accordance with the structuring to be produced. The processing steps can be carried out in the regions of the optical surface in which the photoresist has been removed locally.

In addition, or alternatively, one or more of the processing steps mentioned below can be carried out. Mechanical processing can be carried out, for example for edging the optical surface and/or for processing the substrate contour. A thermal treatment can be carried out in order to, for example, change the state of a layer or of the substrate or for the purpose of soldering or adhesive bonding. In one embodiment, heat treatment is performed outside of vacuum. A chemical treatment is also possible, for example for the purpose of structuring that can be carried out by wet-chemical techniques, from the gas phase or by ion beam etching. In one embodiment, the chemical treatment is effected in combination with a lithographic process. A further variant is irradiation with ions, with electrons, with UV radiation or with X-ray radiation.

The function of the protective layer structure according to the disclosed techniques may consist in providing protection to the optical surface when the processing steps are carried out.

In the case of structuring using a photoresist, the photoresist may be the protective layer of the temporary protective layer structure at the same time. In another embodiment, the photoresist is applied to the protective layer of the temporary protective layer structure. The photoresist can then be removed with the protective layer in a joint method step. It is also possible that the photoresist is removed separately from the protective layer in a preceding method step.

The structuring can serve to subdivide a surface covered throughout by a multilayer system into a multiplicity of mirror elements. The processing steps can be used to remove parts of the mirror body substrate in order to produce flexures within the mirror body substrate such that each of the mirror elements is connected in an articulated manner to a main body of the mirror body substrate by way of a flexure. The mirror body substrate can consist of silicon, in particular of monocrystalline silicon. The function of the temporary protective layer structure according to the disclosed techniques may continue to provide protection to the optical surface—inasmuch as it is retained—during these processing steps. An EUV mirror component comprising a multiplicity of individual mirror elements can be used, for example, as a facet mirror, in particular as a MEMS facet mirror in the illumination system of a microlithographie projection exposure apparatus.

It is also possible to have a sequence of method steps which starts with the processing steps used to subdivide the optical surface into a multiplicity of mirror elements and then leads to the production of the temporary protective layer structure. This opens up the possibility of the temporary protective layer structure protecting outer surfaces of the mirror elements which are located between the optical surface and the flexures.

In one embodiment, the temporary protective layer structure is produced on an optical surface that is not subjected to any further structuring, and so the EUV mirror component has a uniform and continuous optical surface during later use. Such EUV mirrors can be used in an optical system, for example a projection lens of a microlithographic projection exposure apparatus, to deflect and shape an EUV beam path. There are frequently high demands on the geometric shape of the optical surface in the case of these mirrors. In order to be able to satisfy these, the mirror body can consist of a material whose coefficient of thermal expansion has a zero-crossing temperature. An example of such a material is a titanium silicate glass known as ULE™ (Ultra Low Expansion) or ZERODUR™. In such an embodiment, the temporary protective layer structure may primarily have the function of protecting the optical surface during transport and storage and during steps other than those relating to the structuring of the optical surface. For example, these include adhesive steps in which the optical surface is protected from adhesive vapors by the temporary protective layer structure.

In general, metallic materials, monocrystalline materials or glass are also suitable as materials for the substrate of the mirror body. In one embodiment, the mirror substrate material is silicon, in particular monocrystalline silicon.

The temporary protective layer structure can be removed in a separate process before the EUV mirror component is mounted in an optical system. In this procedure, there is a risk of damage to or contamination of the optical surface of the EUV mirror component during the phase between the removal of the temporary protective layer structure and the mounting. In one embodiment, the sacrificial layer is therefore removed only after the EUV mirror component has been mounted in the optical system. This is particularly advantageous if the sacrificial layer is removed using a hydrogen plasma, to which the multilayer system can be exposed in any case during later operation. The protective layer may have been removed in a preceding step prior to the EUV mirror component being mounted. This also encompasses the possibility of removing both the sacrificial layer and the protective layer after the EUV mirror component has been mounted.

The disclosed techniques also relate to an intermediate product of an EUV mirror component. A multilayer system, which forms an optical surface that is highly reflective for EUV radiation, is applied to a surface of the mirror body substrate. A temporary protective layer structure is arranged on the multilayer system. The protective layer structure comprises a protective layer and a sacrificial layer arranged between the protective layer and the multilayer system.

The disclosure encompasses developments of the method with features that are described in the context of the EUV mirror component intermediate product according to the disclosed techniques. The disclosure encompasses developments of the EUV mirror component intermediate product with features that are described in the context of the method according to the disclosed techniques.

### BRIEF DESCRIPTION OF THE DRAWINGS

The techniques disclosed herein are described by way of example below on the basis of advantageous embodiments and with reference to the accompanying drawings, in which:

FIG. 1: shows a microlithographic projection exposure apparatus;

FIG. 2: shows a detail of an EUV mirror component;

FIG. 3: shows the view in accordance with FIG. 2 in a second state of the EUV mirror component;

FIG. 4: shows the view in accordance with FIG. 2 in a third state of the EUV mirror component;

FIG. 5: shows the view in accordance with FIG. 2 in a fourth state of the EUV mirror component,

FIGS. 6-8: show various intermediate states during the manufacture of a facet mirror;

FIG. 9: shows the view in accordance with FIG. 7 in an alternative embodiment of the disclosed techniques;

FIG. 10: shows an illustration of a procedure according to the disclosed techniques;

FIG. 11: shows the view in accordance with FIG. 10 in an alternative embodiment of the disclosed techniques.

### DETAILED DESCRIPTION

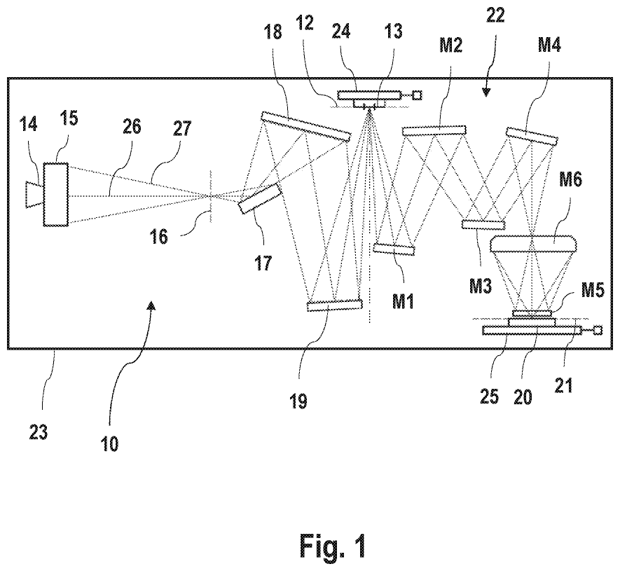

FIG. 1 schematically illustrates a microlithographic EUV projection exposure apparatus. The projection exposure apparatus comprises an exposure beam source 14, an illumination system 10 and a projection lens 22, which are operated jointly in a vacuum chamber 23.

The exposure beam source 14 generates electromagnetic radiation in the EUV range, i.e., at a wavelength of between 5 nm and 30 nm in particular. The exposure radiation emanating from the exposure beam source 14 is focused into an intermediate focal plane 16 by way of a collector 15. Exposure radiation passing across the intermediate focal plane 16 is guided into an object plane 12 by the illumination system 10, with the result that an object field in the object plane 12 is illuminated with uniform radiation intensity.

The illumination system 10 comprises a deflection mirror 17 used to deflect the exposure radiation to a first facet mirror 18. A second facet mirror 19 is disposed downstream of the first facet mirror 18. The second facet mirror 19 is used to image the facets of the first facet mirror 18 into the object plane 12.

A photomask 13 is arranged in the object plane 12 and is imaged into an image plane 21 by way of a plurality of mirrors MI-M6 of the projection lens 22. A structure formed on the photomask 13 is transferred to a radiation-sensitive layer of a wafer 20 arranged in the image plane 21. The photomask 13 is suspended from a first scanning device 24, and the wafer 20 is at rest on a second scanning device 25 such that the wafer 20 can be exposed in a scanning procedure during which the photomask 13 and the wafer 20 are moved synchronously with one another.

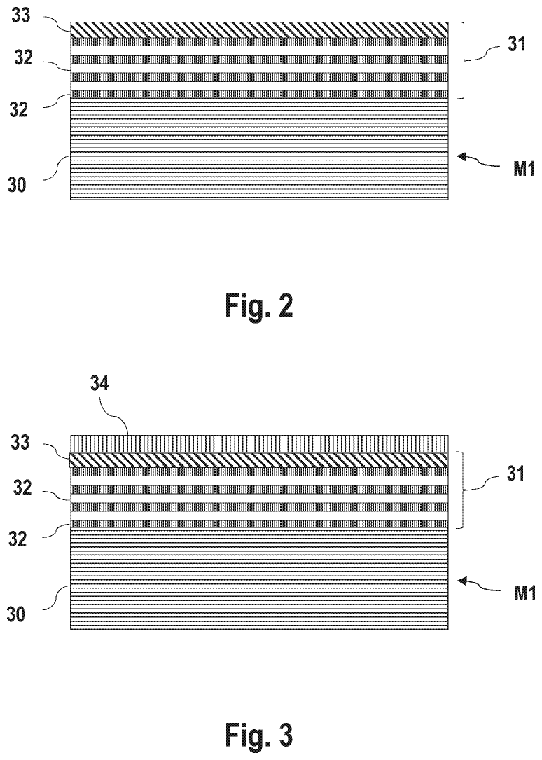

Each of the EUV mirrors 17, 18, 19, M1-M6 in FIG. 1 is provided with a multilayer system which forms an optical surface with high reflectivity for EUV radiation. This is explained in more detail below on the basis of FIG. 2 using the example of the mirror M1. FIG. 2 illustrates an enlarged sectional illustration of a detail of the mirror M1.

The mirror M1 comprises a mirror body 30 made of a mirror substrate material with ultra-low thermal expansion (“ultra-low expansion material”). Examples of such materials include a titanium silicate glass sold under the name ULE™ or ZERODUR™, both of which have a so-called zero-crossing temperature. At this zero-crossing temperature, which is approximately 30° C. for example for ULEM, the coefficient of thermal expansion has in its temperature dependence a zero crossing in the vicinity of which no thermal expansion or only negligible thermal expansion of the mirror substrate material takes place.

A multilayer system 31 with alternating layers 32 of molybdenum and silicon is applied to the mirror body 30. The layers 32 of the multilayer system 31 can each have a thickness of the order of 5 nm, for example. The multilayer system 31 comprises a top layer 33 which has good resistance to influences occurring during the operation of an EUV mirror. The top layer 33 can have a somewhat greater thickness than the other layers 32 of the multilayer system and may be between 1 nm and 20 nm thick, for example. For example, the top layer 33 can consist of ruthenium, TiO₂ or rhenium.

FIG. 2 shows the EUV mirror MI in the state in which it is used in the microlithographic projection exposure apparatus. The top layer 33 of the multilayer system 31 forms the surface of the EUV mirror M1 during operation of the projection exposure apparatus.

The EUV mirror M1 also has the state in accordance with FIG. 2 during manufacture at a point in time immediately after the multilayer system 31 has been applied to the mirror body 30. Between this time and the time at which the EUV mirror M1 is put into service in the projection exposure apparatus, there is an intermediate phase which can extend over a relatively long period of time. During the intermediate phase, the EUV mirror M1 is subjected to various handling steps, for example storage, packaging, transport, unpacking and the like. In the state shown in FIG. 2, the surface of the multilayer system 31 would be exposed directly to the conditions of the surroundings, and this would be associated with a risk of contamination of or damage to the multilayer system 31.

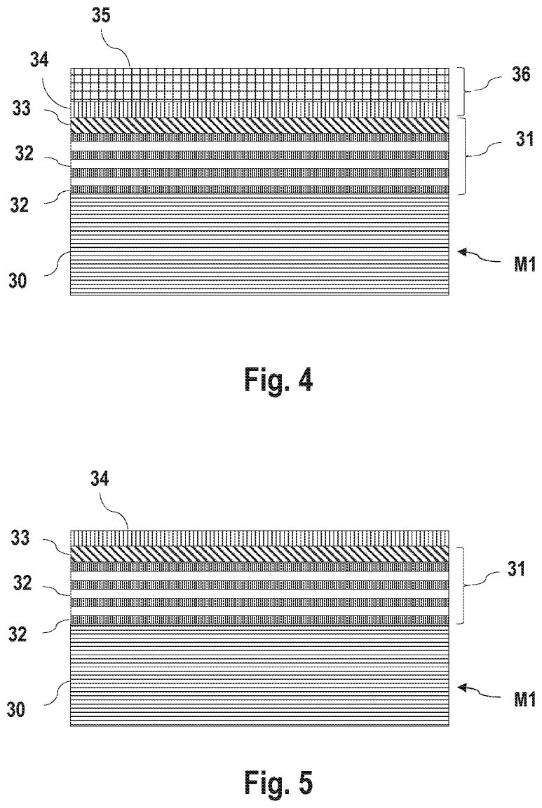

The disclosed techniques propose protecting the multilayer system 31 with a protective layer structure 36 during the intermediate phase; see FIGS. 3, 4. The protective layer structure 36 comprises a sacrificial layer 34 and a protective layer 35, which are applied to the surface of the EUV mirror in succession. The sacrificial layer 34 is optimized such that it forms a good base for the application of the protective layer 35 and that it can be removed again easily and, in particular, without residue before the EUV mirror MI is put into service, without the top layer 33 of the multilayer system 31 being damaged. The protective layer 35 is optimized for a good protective effect in order to ensure that conditions during the intermediate phase cannot cause damage to the multilayer system 31. The requirement of more aggressive steps for removing the protective layer 34 again before the EUV mirror MI is put into service is acceptable because the sacrificial layer 34 lying therebelow prevents the aggressive steps from being able to have an effect down into the multilayer system 31.

FIG. 3 shows the EUV mirror MI in a state in which the sacrificial layer 34 is applied to the top layer 33 of the multilayer system 31. The sacrificial layer 34 is applied in the same process chamber in which the top layer 33 of the multilayer system 31 has also been applied beforehand. Both the top layer 33 and the sacrificial layer 34 are applied in vacuo, with the vacuum being maintained continuously during the two steps and between the two steps. The sacrificial layer 34 has a surface that provides a good base for the subsequent protective layer 35.

The protective layer 35 can be applied in a separate process chamber. A state of the EUV mirror MI in which the complete protective layer structure 36 with the sacrificial layer 34 and the protective layer 35 has been applied is shown in FIG. 4.

The protective layer structure 36 is removed again before the EUV mirror MI is put into service. FIG. 5 shows an intermediate state in which the protective layer 35 has been removed and the sacrificial layer 34 is still present in the state that it has following the action of the aggressive method steps used to remove the protective layer 35. In particular, the sacrificial layer may have an uneven and/or damaged surface that is unsuitable for the application of further layers.

After the remaining sacrificial layer 34 has also been removed with a gentler method, the EUV mirror MI is back in the state shown in FIG. 2. The EUV mirror MI is ready to be put into service in the microlithographic projection exposure apparatus.

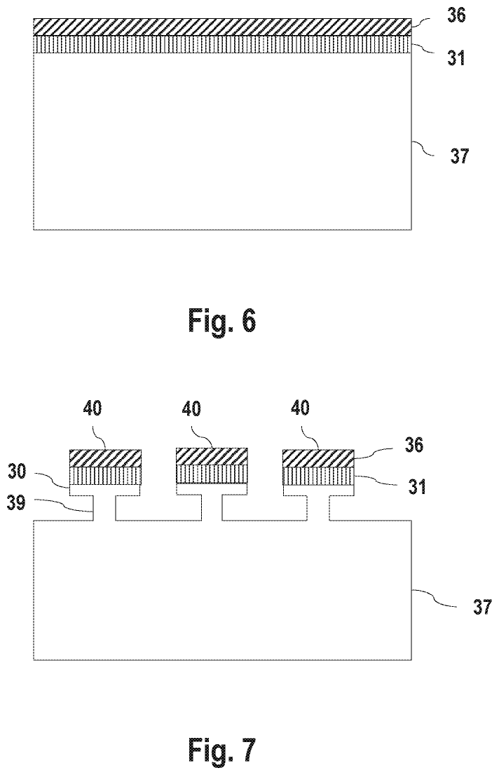

FIGS. 6-8 illustrate various stages in the manufacture of a component for the first facet mirror 18 or the second facet mirror 19 of the microlithographic projection exposure apparatus from FIG. 1. A substrate body 37 consisting of monocrystalline, polycrystalline or amorphous silicon is provided. A multilayer system 31 corresponding to FIG. 2 is applied to a surface of the substrate body 37.

A protective layer structure 36 whose protective layer 35 is formed by a photoresist is applied to the multilayer system 31. Regions in which material is removed by a subsequent processing step are defined by suitable exposure of the photoresist. FIG. 7 shows a state in which material is removed from between individual EUV mirror components 40 such that the EUV mirror components 40 are separated from one another as far as into the substrate body 37. Each EUV mirror component 40 has a mirror body 30, which is connected to the remaining base of the substrate body 37 via a schematically illustrated flexure 39. The protective layer structure 36 ensures that the multilayer system 31 is not damaged in the regions in which it is intended to form the optical surface of the EUV mirror components 40.

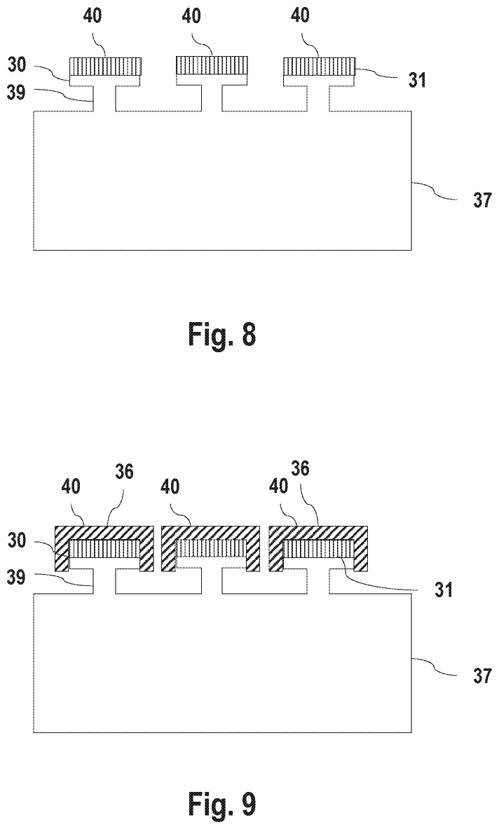

Each of the facet mirrors 18, 19 is composed of a plurality of components of the type shown in FIG. 7. Before a facet mirror 18, 19 is put into service in the microlithographic projection exposure apparatus, the protective layer structure 36 is removed such that the EUV mirror components 40 obtain their final state, which is shown in FIG. 8.

FIG. 9 indicates an alternative exemplary embodiment in which the multilayer system 31 is applied only after suitable structuring of the substrate body 37. A protective layer structure 36 that protects the optical surface and the side faces of the EUV mirror components 40 is applied to the multilayer system 31.

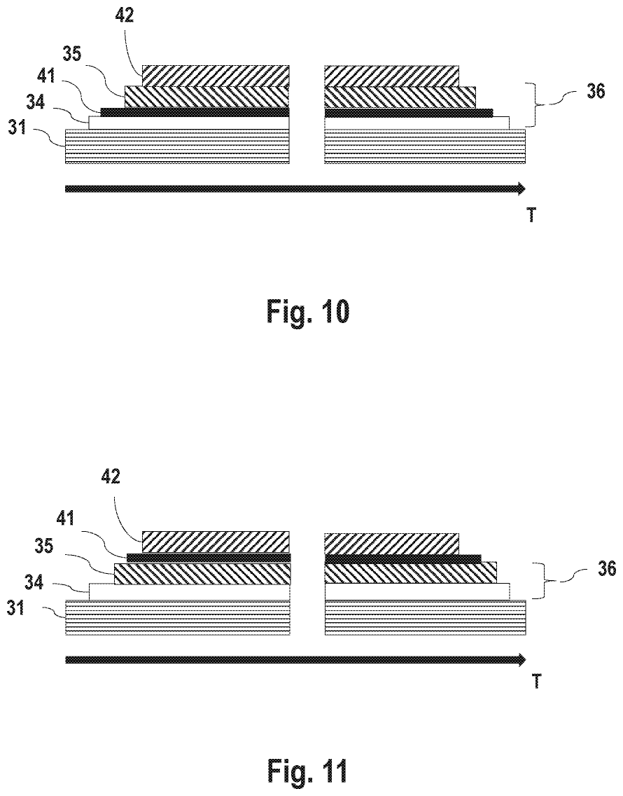

An exemplary embodiment of a protective layer structure 36 according to the disclosed techniques is explained with reference to FIG. 10. The sequence in which layers on the surface of the mirror body are added and removed again is shown above a schematic timeline arrow T. In a first step, a carbon layer with a thickness of between 2 nm and 5 nm is applied to the top layer 33 of the multilayer system 31 by vapor deposition. The carbon layer forms a sacrificial layer 34 in the sense of the disclosed techniques.

The subsequent step used to apply the protective layer 35 is carried out in another process chamber. During transport there, the EUV mirror in the exemplary embodiment shown is exposed to an oxygen-containing atmosphere, which has the effect that the sacrificial layer 34 can oxidize and that impurities are deposited. FIG. 10 shows a corresponding contamination layer 41 on the sacrificial layer 34. There are other exemplary embodiments without such a contamination layer.

The protective layer 35 is applied to the contamination layer 41. In this exemplary embodiment, the protective layer 35 is formed by a protective lacquer which is applied by way of spin coating. The protective lacquer has a thickness of between 1 μm and 10 μm.

A photoresist 42 is again applied to the protective layer 35 by way of the spin coating. The photoresist 42 can be selectively exposed in order to define regions for subsequent structuring.

Before the EUV mirror is put into service in the projection exposure apparatus, the layers are successively removed again until the top layer of the multilayer system 31 is exposed. Initially, solvents are used to remove the photoresist 42 and the protective lacquer 35 by wet-chemical techniques. The sacrificial layer 34 made of carbon is not attacked by the solvents. The contamination layer 41 is removed by exposing the surface of the EUV mirror to an oxygen plasma should the sacrificial layer be insensitive thereto. The sacrificial layer 34 is removed by exposing the surface of the EUV mirror to a hydrogen plasma only once the EUV mirror has been installed in the projection exposure apparatus. Subsequently, the projection exposure apparatus with the EUV mirror is ready for use.

The carbon material of the sacrificial layer 34 has a lower surface energy than metals, and so good coverage of the multilayer system 31 by the top layer 33 can be expected. This promotes the residue-free removal of the sacrificial layer 34 from the top layer 33. The wet chemical processes for removing the photoresist 42 and the protective layer 35 facilitate the removal of particles and contaminants both on and in the layers. Since only chemical processes and no physical etching processes are used to remove the layers, the material is removed very selectively.

In the exemplary embodiment according to FIG. 11, the sacrificial layer 34 is produced by oxidation of the top layer 33 of the multilayer system 31. An oxide layer with a thickness of a few nanometers is formed. A protective layer 35 made of silicon dioxide, which is between 100 nm and 300 nm thick, is applied to the oxide layer 34 by way of vapor deposition. A contamination layer 41 might form on the protective layer 35 during subsequent storage of the EUV mirror. The photoresist 42 for structuring the surface is applied to the contamination layer 41 by way of spin coating. Once again, the thickness of the photoresist layer is between 1 μm and 10 μm.

The layers are removed before the EUV mirror is put into service in the projection exposure apparatus. Once again, the photoresist 42 is removed by using solvents. The contamination layer 41 is removed by applying an oxygen plasma. The protective layer made of silicon dioxide can be removed by using HF vapor etching. For example, a hydrogen plasma may be applied in order to remove the oxide layer that forms the sacrificial layer 34. Alternatively, the sacrificial layer can be removed by physical sputtering (e.g., noble gas plasma) or by applying HF vapor etching.

This exemplary embodiment is advantageous in that there is no need for a separate deposition of the sacrificial layer 34. The multilayer system 31 is spared by virtue of the protective layer structure 36 being removed by dry-chemical methods. Contamination and particles can be reliably removed both on and in the layer by virtue of the protective layer 35 being removed by the application of HF vapor etching. Separation of the functionalities is facilitated by using complementary deposition and removal methods. Potentially incomplete removal of the sacrificial layer 34 can be acceptable because small residues of the oxide of the top layer 33 do not significantly impair the reflectivity of the multilayer system 31 for EUV radiation.

What is claimed is:

1. A method for manufacturing an EUV mirror component, comprising:
forming an optical surface that is highly reflective for EUV radiation by applying a multilayer system to a surface of a mirror body substrate;
producing a temporary protective layer structure on the multilayer system, wherein the temporary protective layer structure comprises a protective layer and a sacrificial layer arranged between the protective layer and the multilayer system, and wherein the sacrificial layer is a layer produced by oxidation of a layer of the multilayer system; and
removing the temporary protective layer structure from the mirror body substrate before the EUV mirror component is put into service.

2. The method of claim 1, wherein the multilayer system comprises a top layer which consists of a different material than underlying alternating layers of the multilayer system.

3. The method of claim 1, wherein the sacrificial layer is a layer applied to the multilayer system.

4. The method of claim 3, wherein the sacrificial layer is a carbon layer.

5. The method of claim 4, wherein the carbon layer has a thickness of between 1 nm and 30 nm, preferably between 2 nm and 5 nm.

6. The method of claim 1, wherein the sacrificial layer is a layer produced by oxidation of a layer of the multilayer system.

7. The method of claim 1, wherein the protective layer is applied as a protective lacquer.

8. The method of claim 7, wherein the protective lacquer is a photoresist.

9. The method of claim 1, wherein the protective layer is formed by silicon dioxide.

10. The method of claim 1, wherein a temperature of 350° C. is not exceeded during the removing of the temporary protective layer structure.

11. The method of claim 1, wherein the EUV mirror component is subjected to a processing step, in which material is removed from the multilayer system and/or from the mirror body substrate, after the producing and before the removing of the temporary protective layer structure.

12. The method of claim 11, wherein a surface covered throughout by a multilayer system is subdivided into a multiplicity of mirror elements.

13. An apparatus comprising:
multilayer system that is applied to a surface of a mirror body substrate and forms an optical surface that is highly reflective for EUV radiation,
a temporary protective layer structure arranged on the multilayer system comprising a protective layer and a sacrificial layer arranged between the protective layer and the multilayer system, and wherein the sacrificial layer is a layer produced by oxidation of a layer of the multilayer system.

14. The apparatus of claim 13, wherein the apparatus comprises an EUV mirror component intermediate product.

15. The apparatus of claim 14, wherein the temporary protective layer structure is configured for removal from the EUV mirror component intermediate product prior to putting the apparatus in use in an EUV lithographic device.

16. The apparatus of claim 13, wherein the sacrificial layer comprises a material formed via oxidation of a material of the multilayer system.

17. The apparatus of claim 13, wherein the sacrificial layer comprises a carbon layer.

18. The apparatus of claim 13, wherein the protective layer comprises a protective lacquer.

19. The apparatus of claim 18, wherein the protective lacquer comprises photoresist.

20. The apparatus of claim 13, wherein the protective layer comprises silicon dioxide.
